(19) United States
(12) Patent Application Publication
(10) Pub. No.: US 2013/0314874 A1
(43) Pub. Date: Nov. 28, 2013

(54) HEAT RADIATION SYSTEM FOR POWER MODULE

(71) Applicant: Jong Man KIM, Gyunggi-do (KR)

(72) Inventor: Jong Man KIM, Gyunggi-do (KR)

(73) Assignee: SAMSUNG ELECTRO-MECHANICS CO., LTD., Gyunggi-do (KR)

(21) Appl. No.: 13/549,246

(22) Filed: Jul. 13, 2012

(30) Foreign Application Priority Data
May 23, 2012 (KR) 10-2012-0054754

(51) Int. Cl. H05K 7/20

(52) U.S. Cl. 361/698; 361/689

(57) ABSTRACT

Disclosed herein is a heat radiation system for a power module, including: a heat radiation member having an internal space and a cooling medium circulated in the internal space; a heat generation module formed on the heat radiation member; and a pair of electrodes formed at regions facing each other in the internal space of the heat radiation member and having different volumes.

### CROSS REFERENCE TO RELATED APPLICATION

This application claims the benefit of Korean Patent Application No. 10-2012-0054754, filed on May 23, 2012, entitled “Heat Dissipation System for Power Module”, which is hereby incorporated by reference in its entirety into this application.

### BACKGROUND OF THE INVENTION

1. Technical Field

The present invention relates to a heat radiation system for a power module.

2. Description of the Related Art

In accordance with the trend toward an increase in power device output density of a power module, heat radiation characteristics have been an important issue in view of module reliability.

Meanwhile, in accordance with an increase in capacity of the power module, a heat radiation device capable of efficiently radiating heat generated in a power device has been demanded.

Up to now, in the heat radiation device, an air cooling scheme of using an aluminum heat sink, heat spreader, or heat pipe has been used as disclosed in Patent Document 1. However, the air cooling scheme has reached the limit. Therefore, a water cooling scheme having an excellent heat transfer coefficient has been adopted in order to solve a heat radiation problem.

### PRIOR ART DOCUMENT

### Patent Document

(Patent Document 1) US 2011-0017496 A

### SUMMARY OF THE INVENTION

The present invention has been made in an effort to provide a heat radiation system for a power module capable of improving heat radiation efficiency by increasing a flow speed of a cooling medium.

According to a preferred embodiment of the present invention, there is provided a heat radiation system for a power module, including: a heat radiation member having an internal space and a cooling medium circulated in the internal space; a heat generation module formed on the heat radiation member; and a pair of electrodes formed at regions facing each other in the internal space of the heat radiation member and having different volumes.

The heat radiation member may include a first surface, a second surface, a third surface, and a fourth surface, the internal space may be divided into a center region and an edge region, and the pair of electrodes may be formed to face each other at edge regions of the second and fourth surfaces of the heat radiation member.

The number of electrode pairs may be plural, the heat radiation member may include a first surface, a second surface, a third surface, and a fourth surface, the internal space may be divided into a center region and an edge region, and the pair of electrodes may be formed to face each other at edge regions of one side of the second and fourth surfaces of the heat radiation member, respectively, and another pair of electrodes may be formed to face each other at edge regions of the other side of the second and fourth surfaces of the heat radiation member, respectively.

The heat radiation member may include a first surface, a second surface, a third surface, and a fourth surface, and the pair of electrodes may be formed at the first and third surfaces facing each other based on a length direction of the heat radiation member.

The heat generation module may be formed at a lower portion of the heat radiation member.

The heat radiation system may further include a power supply connected to the pair of electrodes to supply power thereto.

The power supply may supply direct current (DC) power.

The heat radiation member may be made of a metal material or an insulating material.

The heat generation module may include a power device.

The cooling medium may be a refrigerant, cooling water, air, or a mixture of cooling water and air.

The heat radiation member may have a closed-loop shape.

According to another preferred embodiment of the present invention, there is provided a heat radiation system for a power module, including: a heat radiation member having an internal space and a cooling medium circulated in the internal space; and a pair of electrodes formed at regions facing each other in the internal space of the heat radiation member and having different volumes.

The heat radiation system may further include a power supply connected to the pair of electrodes to supply power thereto.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a configuration of a heat radiation system for a power module according to a preferred embodiment of the present invention;

FIG. 2 is a view showing a configuration of a heat radiation system for a power module according to another preferred embodiment of the present invention; and

FIG. 3 is a view showing a configuration of a heat radiation system for a power module according to still another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

### Heat Radiation System for Power Module

### First Preferred Embodiment

FIG. 1 is a view showing a configuration of a heat radiation system for a power module according to a preferred embodiment of the present invention.

As shown in FIG. 1, the heat radiation system 100 for a power module may be configured to include a heat radiation member 110 having an internal space A and a cooling medium circulated in the internal space A, a heat generation module 120 formed on the heat radiation member 110, and a pair of electrodes 131 and 132 formed at regions facing each other in the internal space A of the heat radiation member 110 and having different volumes.

In addition, the heat radiation system 100 for a power module may further include a power supply 140 connected to the pair of electrodes 131 and 132 to supply power thereto.

Here, the power supply 140 may supply direct current (DC) power, but is not limited thereto.

Further, the heat radiation member 110 may include a first surface 110a, a second surface 110b, a third surface 110c, and a fourth surface 110d.

Further, the internal space A of the heat radiation member 110 may be divided into a center region and an edge region.

As shown in FIG. 1, the pair of electrodes 131 and 132 may be formed to face each other at edge regions of the second and fourth surfaces 110b and 110d of the heat radiation member 110.

More specifically, according to the preferred embodiment of the present invention, in order to increase a flow speed of the cooling medium in the heat radiation member 110, the pair of electrodes 131 and 132 having different volumes is formed to face each other, thereby forming non-uniform electromagnetic fields in a fluid. This forms a dipole in the fluid to accelerate a flow of the fluid.

As shown in FIG. 1, the cooling medium in the heat radiation member 110 is circulated from a lower portion of the heat radiation member 110 toward an upper portion thereof according to heat generated from the heat generation module 120. At this time, a phenomenon that a flow speed of the cooling medium becomes slower toward the edge region of the heat radiation member 110 occurs.

Therefore, according to the preferred embodiment of the present invention, the pair of electrodes having different volumes is disposed so as to face each other at positions corresponding to the edge regions of the heat radiation member 110 to generate an electro-osmosis phenomenon, thereby performing a pumping action on the flow of the fluid.

Therefore, the flow speed of the cooling medium is rapidly maintained even in the edge region of the heat radiation member 110, such that the entire heat radiation efficiency of the heat radiation member 110 may be improved.

In addition, according to the preferred embodiment of the present invention, the flow of the cooling medium in the heat radiation member 110 may be controlled without a separate apparatus such as a mechanical pump for accelerating the flow of the fluid.

Further, the heat generation module 120 may be formed at a lower portion of the heat radiation member 110.

In the case in which the heat generation module 120 is positioned at the lower portion of the heat radiation member 110, when the heat is generated from the heat generation module 120, since the flow of the cooling medium may be smoothly induced due to a property of the heat that is to move upwardly, the flow of the fluid may be smoothed.

Further, the heat radiation member 110 may be made of a metal material or an insulating material.

For example, the metal material may be copper, aluminum, or the like. However, the metal material is not limited thereto, but may be any material having excellent heat radiation efficiency.

Further, the heat generation module 120 may include a power device.

In addition, the cooling medium may be a refrigerant, cooling water, air, or a mixture of cooling water and air.

Further, the heat radiation member 110 may have a closed-loop shape.

As shown in FIGS. 1 to 3, the heat radiation system 100 for a power module uses a natural circulation scheme in which the fluid is cooled by evaporation of the fluid due to absorption of the heat from the heat generation module 120, movement of the fluid due to a pressure difference, and condensation due to heat radiation, in the internal space A of the heat radiation member 110 having the closed-loop shape.

According to the preferred embodiment of the present invention, the electrodes having different volumes are used, such that the fluid is evaporated at a rapid speed and pressure of the fluid is increased to increase the flow speed of the fluid, thereby making it possible to rapidly lower a device temperature of the heat generation module 120.

### Heat Radiation System for Power Module

### Second Preferred Embodiment

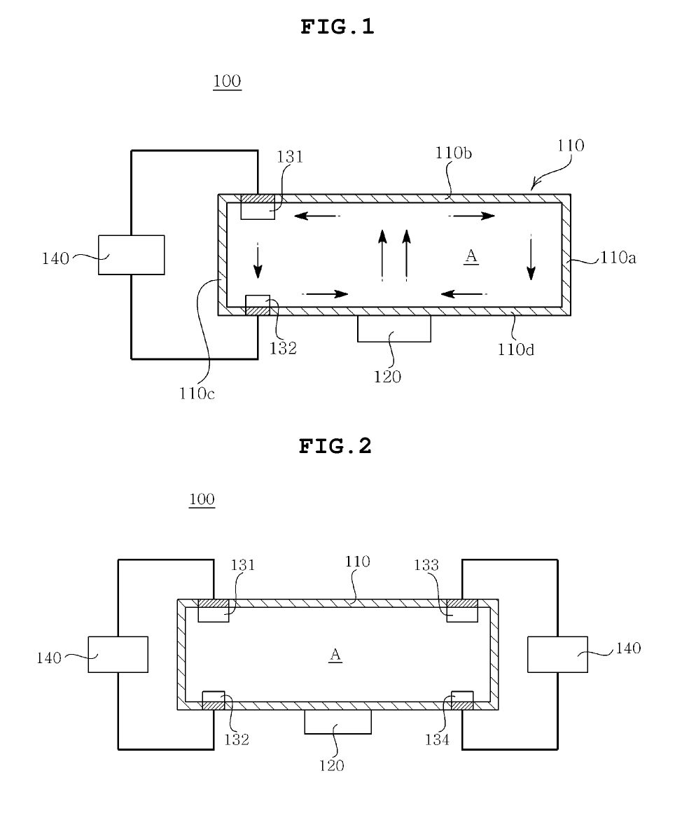

FIG. 2 is a view showing a configuration of a heat radiation system for a power module according to another preferred embodiment of the present invention.

However, in the second preferred embodiment of the present invention, a description for the same components as those of the first preferred embodiment of the present invention will be omitted and only a description for components different therefrom will be provided.

As shown in FIG. 2, the heat radiation system 100 for a power module may be configured to include a heat radiation member 110 having an internal space A and a cooling medium circulated in the internal space A, a heat generation module 120 formed on the heat radiation member 110, and a pair of electrodes formed at regions facing each other in the internal space A of the heat radiation member 110 and having different volumes.

In addition, the heat radiation system 100 for a power module may further include a power supply 140 connected to each of a pair of electrodes 131 and 132 and another pair of electrodes 133 and 134 to supply power thereto.

Here, the power supply 140 may supply direct current (DC) power, but is not limited thereto.

Further, as shown in FIG. 1, the heat radiation member 110 may include a first surface 110a, a second surface 110b, a third surface 110c, and a fourth surface 110d.

Further, the internal space A of the heat radiation member 110 may be divided into a center region and an edge region.

As shown in FIG. 2, the number of electrode pairs may be plural. That is, the number of electrode pair groups may be multiple.

That is, as shown in FIG. 2, in the case in which the number of electrode pairs is plural, a pair of electrodes 131 and 132 may be formed to face each other at edge regions of one side of the second and fourth surfaces 110b and 110d of the heat radiation member 110, respectively, and another pair of electrodes 133 and 134 may be formed to face each other at edge regions of the other side of the second and fourth surfaces 110b and 110d of the heat radiation member 110, respectively.

More specifically, according to the preferred embodiment of the present invention, in order to increase a flow speed of the cooling medium in the heat radiation member 110, two pairs of electrodes 131 and 132 and 133 and 134 having different volumes are formed to face each other, respectively, thereby forming non-uniform electromagnetic fields in a fluid. This forms a dipole in the fluid to accelerate a flow of the fluid.

### Heat Radiation System for Power Module

### Third Preferred Embodiment

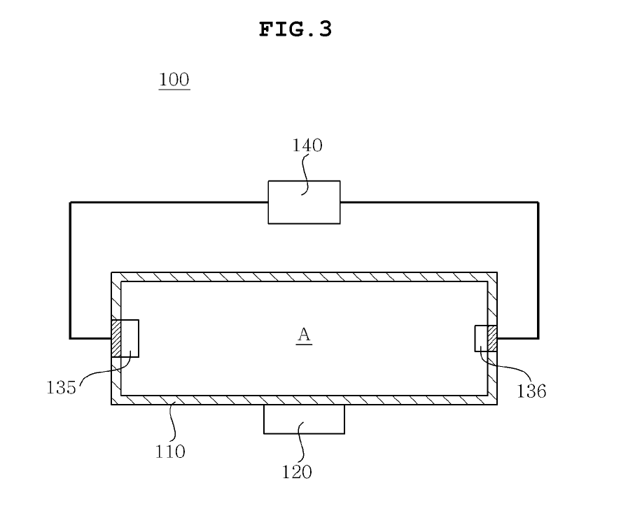

FIG. 3 is a view showing a configuration of a heat radiation system for a power module according to still another preferred embodiment of the present invention.

However, in the third preferred embodiment of the present invention, a description for the same components as those of the first preferred embodiment of the present invention will be omitted and only a description for components different therefrom will be provided.

As shown in FIG. 3, the heat radiation system 100 for a power module may be configured to include a heat radiation member 110 having an internal space A and a cooling medium circulated in the internal space A, a heat generation module 120 formed on the heat radiation member 110, and a pair of electrodes formed at regions facing each other in the internal space A of the heat radiation member 110 and having different volumes.

As shown in FIG. 3, a pair of electrodes 135 and 136 may be formed at first and third surfaces 110a and 110c facing each other based on a length direction of the heat radiation member 110.

The electrodes 131, 132, 133, 134, 135, and 136 are not limited to being disposed as described above with reference to FIGS. 1 to 3, but may be disposed at any region as long as they may rapidly induce the flow of the cooling medium in the heat radiation member 110.

As set forth above, in the heat radiation system for a power module according to the preferred embodiment of the present invention, the electrodes disposed in the internal space of the heat radiation member and having different volumes serve to pump the cooling medium to accelerate the flow of the cooling medium, thereby making it possible to increase the flow speed.

In addition, according to the preferred embodiment of the present invention, the flow speed of the cooling medium is increased, such that the heat generated from the heat generation module is efficiently radiated, thereby making it possible to improve heat radiation characteristics.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A heat radiation system for a power module, comprising:
a heat radiation member having an internal space and a cooling medium circulated in the internal space;
a heat generation module formed on the heat radiation member; and
a pair of electrodes formed at regions facing each other in the internal space of the heat radiation member and having different volumes.

2. The heat radiation system as set forth in claim 1, wherein the heat radiation member includes a first surface, a second surface, a third surface, and a fourth surface, and the internal space is divided into a center region and an edge region, and
the pair of electrodes is formed to face each other at edge regions of the second and fourth surfaces of the heat radiation member.

3. The heat radiation system as set forth in claim 1, wherein the number of electrode pairs is plural,
the heat radiation member includes a first surface, a second surface, a third surface, and a fourth surface, and the internal space is divided into a center region and an edge region, and
the pair of electrodes is formed to face each other at edge regions of one side of the second and fourth surfaces of the heat radiation member, respectively, and another pair of electrodes is formed to face each other at edge regions of the other side of the second and fourth surfaces of the heat radiation member, respectively.

4. The heat radiation system as set forth in claim 1, wherein the heat radiation member includes a first surface, a second surface, a third surface, and a fourth surface, and
the pair of electrodes is formed at the first and third surfaces facing each other based on a length direction of the heat radiation member.

5. The heat radiation system as set forth in claim 1, wherein the heat generation module is formed at a lower portion of the heat radiation member.

6. The heat radiation system as set forth in claim 1, further comprising a power supply connected to the pair of electrodes to supply power thereto.

7. The heat radiation system as set forth in claim 6, wherein the power supply supplies direct current (DC) power.

8. The heat radiation system as set forth in claim 1, wherein the heat radiation member is made of a metal material or an insulating material.

9. The heat radiation system as set forth in claim 1, wherein the heat generation module includes a power device.

10. The heat radiation system as set forth in claim 1, wherein the cooling medium is a refrigerant, cooling water, air, or a mixture of cooling water and air.

11. The heat radiation system as set forth in claim 1, wherein the heat radiation member has a closed-loop shape.

12. A heat radiation system for a power module, comprising:
a heat radiation member having an internal space and a cooling medium circulated in the internal space; and
a pair of electrodes formed at regions facing each other in the internal space of the heat radiation member and having different volumes.

13. The heat radiation system as set forth in claim 12, further comprising a power supply connected to the pair of electrodes to supply power thereto.
